(19) United States
(12) Patent Application Publication
(10) Pub. No.: US 2026/0150321 A1
(43) Pub. Date: May 28, 2026

(54) BUFFER LAYER FOR HIGH ELECTRON MOBILITY TRANSISTORS AND METHODS OF MANUFACTURING THE SAME

(71) Applicant: Texas Instruments Incorporated, Dallas, TX (US)

(72) Inventors: Chang Soo Suh, Allen, TX (US); Qhalid Fareed, Plano, TX (US); James Teherani, Plano, TX (US); Pilsung Park, Dallas, TX (US); Yoganand Saripalli, Allen, TX (US); Shoji Wada, McKinney, TX (US)

(21) Appl. No.: 18/962,173

(22) Filed: Nov. 27, 2024

(51) Int. Cl. H10D 30/47; H01L 21/02; H10D 30/01; H10D 62/85

(52) U.S. Cl. CPC H10D 30/475; H10D 30/015; H10D 62/8503; H10P 14/3216; H10P 14/3416

(57) ABSTRACT

Disclosed herein is device including a III-N buffer layer disposed over a substrate, the III-N buffer layer including a carbon doped aluminum gallium nitride layer, a first III-N material layer disposed over and interfacing with the carbon doped aluminum gallium nitride layer, a second III-N material layer disposed over the first III-N material layer, the first and second III-N material layers forming a heterojunction structure, wherein the first III-N material layer includes a channel proximate to an interface between the first and second III-N material layers, and a gate structure disposed over the second III-N material layer.

### FIELD

The present disclosure generally relates to semiconductor devices, and more particularly, to high electron mobility semiconductor devices.

### BACKGROUND

A type of semiconductor device is a high electron mobility transistor (HEMT). A HEMT typically employs different semiconductor materials to form a heterojunction, where a channel may be formed near the heterojunction and between a source and a drain. A HEMT may support a high-speed operation, which makes HEMTs attractive for high frequency applications, among others.

### SUMMARY

Disclosed herein is a device including a III-N buffer layer disposed over a substrate, the III-N buffer layer including a carbon doped aluminum gallium nitride layer, a first III-N material layer disposed over and interfacing with the carbon doped aluminum gallium nitride layer, a second III-N material layer disposed over the first III-N material layer, the first and second III-N material layers forming a heterojunction structure, wherein the first III-N material layer includes a channel proximate to an interface between the first and second III-N material layers, and a gate structure disposed over the second III-N material layer.

Also disclosed herein is a device including a III-N buffer layer disposed over a substrate, the III-N buffer layer including a carbon doped aluminum gallium nitride layer, a III-N back-barrier layer disposed over the III-N buffer layer, a first III-N material layer disposed over the III-N back-barrier layer, a second III-N material layer disposed over the first III-N material layer, the first and second III-N material layers forming a heterojunction structure, wherein the first III-N material layer includes a channel proximate an interface between the first and second III-N material layers, and a gate structure disposed over the second III-N material layer.

Also disclosed herein is a method including forming a carbon doped aluminum gallium nitride layer over a substrate, forming a first III-N material layer over the carbon doped aluminum gallium nitride layer, forming a second III-N material layer on the first III-N material layer, the first and second III-N material layers forming a heterojunction structure, wherein the first III-N material layer includes a channel proximate to an interface between the first and second III-N material layers, and forming a gate structure over the second III-N material layer.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a flowchart for a method forming a semiconductor device, in accordance with various examples.

FIGS. 2A, 2B, and 2C illustrate cross-section views of a semiconductor device, in accordance with the process of FIG. 1 and the various examples associated therewith.

FIG. 3 illustrates a cross-section view of a semiconductor device, in accordance with the process of FIG. 1 and the various examples associated therewith.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent example functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice of other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended for simplicity and clarity of description and is not intended to form or dictate a relationship between different examples described herein. The examples and descriptions provided herein are intended to be illustrative and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two. For example, “on” may be used to indicate direct contact between the two and “over” may be used to indicate one or more intervening layers between the two.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

High electron mobility transistor (HEMT) devices may be used for a variety of applications, including power switching and high power applications. Similar to other semiconductor devices, HEMT devices may be formed over a semiconductor substrate (or wafer). In some examples, semiconductor substrates, or wafers, may be cut from silicon ingots to form a silicon substrate. In various examples, the silicon ingot may be formed to provide <111>, <110>, or <100> crystallographic orientation for silicon substrates cut perpendicular (e.g., 0°cut) to the length of the ingot. In manufacturing a silicon substrate having a <111> silicon crystallographic orientation, the silicon ingot may be cut perpendicular (e.g., 0° cut) to length of the ingot to create a silicon substrate where the <111> crystallographic orientation is perpendicular to a top surface of the silicon substrate. In some cases (e.g., due to statistical variations in process steps associated with cutting the silicon ingot), the silicon ingot may be cut at a non-perpendicular angle (e.g., about 0.2° to about 0.5° from perpendicular) to the length of the of the ingot to create a silicon substrate where the <111> crystallographic orientation of the silicon is non-perpendicular (e.g., acute angled) to a top surface of the substrate. Such non-perpendicularly cut wafers are sometimes referred to as miscut wafers (or miscut substrates) because these wafers were intended to be cut perpendicularly, but instead were cut non-perpendicularly (e.g., about 0.2° to about 0.5° from perpendicular).

Generally, silicon wafers having a miscut may be used as a substrate for forming (e.g., growing) various semiconductor layers (e.g., III-N semiconductor layers described herein) for fabricating HEMT devices. In that regard, even though a silicon wafer may be miscut (or non-perpendicularly cut), these miscut wafers still provide a good morphology for the various semiconductor layers for forming HEMT and other higher mobility structures thereon. In various examples, the miscut wafers may have a <111> crystallographic orientation. In other examples, the miscut wafers may have a <110> or <100> crystallographic orientation. In various examples, the substrate having <111> crystallographic orientation may be more beneficial to the formation of various semiconductor layers to fabricate HEMT and other high mobility structures—e.g., compared to substrates having <100> or <110> crystallographic orientation. However, as described below, while the silicon substrate having <111> crystallographic orientation may be preferred, issues may arise in forming HEMT devices if the silicon substrate is miscut - e.g., having a miscut angle of greater than 0.2° from perpendicular.

For the purposes of this description, the term “III-N” refers to semiconductor materials in which group III elements, such as aluminum, gallium, and indium, and possibly boron, provide a portion of the atoms in the semiconductor material and nitrogen atoms provide another portion of the atoms in the semiconductor material. Examples of III-N semiconductor materials include gallium nitride, boron gallium nitride, aluminum gallium nitride, indium nitride, and indium aluminum gallium nitride. Additionally, terms describing elemental formulas of materials do not imply a particular stoichiometry of the elements. For example, aluminum gallium nitride may be written as AlGaN, which covers a range of relative proportions of aluminum and gallium.

Generally, a HEMT device, such as a GaN device (or a III-N semiconductor device), includes a buffer layer formed over a silicon substrate, a channel layer formed over the buffer layer, and a gate stack formed over the channel layer. HEMTs can be configured as enhancement-mode (E-mode HEMT) devices or depletion-mode HEMT (D-mode HEMT). The E-mode HEMTs are configured to have the charge carriers (e.g., electrons in two-dimensional electron gas) depleted (e.g., absent) under the gate stack resulting in normally OFF devices. The E-mode HEMTs can be turned ON by applying a positive voltage to the gate stack. On the other hand, the D-mode HEMTs are configured to have the charge carriers (e.g., electrons in two-dimensional electron gas) present under a gate stack resulting in normally ON devices. The D-mode HEMTs devices can be turned OFF by applying a negative voltage to the gate stack. It is understood that the methods and structures disclosed herein are applicable to both E-mode HEMTs and D-mode HEMTs, although descriptions herein are primarily associated with E-mode HEMTs.

The gate stack, or gate structure, of E-mode HEMTs generally include a p-type gallium nitride (pGaN) layer (e.g., gate layer) formed in a gate region over a semiconductor substrate. However, in various examples, the formation of a pGaN material layer over a miscut substrate may lead to the formation of a pGaN material layer having an uneven thickness over the substrate. In that regard, it has been observed, that a miscut substrate (e.g., substrates cut at a non-perpendicular angle (e.g., about 0.2° to about 0.5° from perpendicular) to the length of the ingot to create the substrate) may have a rough (e.g., stepped profile or non-smooth) top surface that may imprint morphological deformations into layers formed thereover. As such, the morphology of each successive layer formed over a miscut wafer is effected by the rough (e.g., stepped) top surface of the miscut substrate. This in turn, may lead to layers (e.g., III-N semiconductor layers) formed thereover having a similar stepped surface (e.g., rough surface) that may cause uneven formation of subsequently formed layers thereon.

For example, in HEMT devices, formation of a pGaN material layer on a underlaying material layer (e.g., barrier layer) having a stepped profile top surface may lead to the formation of pGaN material layer having an uneven thickness over the substrate. This may be attributed to the stepped profile of the underlying material layer causing excessive accumulation of pGaN material at the various deformations (e.g., steps) along the surface of the underlying material layer (e.g., barrier layer). The accumulated, or excess, pGaN material may, in various examples, cause the formed pGaN material layer to have an uneven thickness. During patterning (e.g., etching) of such a pGaN material layer to form a gate layer of the HEMT device, it may be difficult to completely etch the pGaN material layer outside the gate region due to the uneven thickness. As a result, unintended portions of the pGaN material layer may remain unetched (or having non-zero thicknesses) during the pGaN gate etch process leading to unintended pGaN stringers being formed in the HEMT device. For example, such pGaN stringers may form a direct electrical connection (or pathway) between the gate and drain of a HEMT. Thus, the pGaN stringers may cause leakage current between the gate and drain and/or between source and drain resulting in poor device performance and/or failure of the HEMT device. In various examples, the pGaN stringers may also result in drain punch through at very low drain bias.

Described herein are methods for overcoming the accumulation of excess pGaN material that may lead to pGaN stringers in HEMTs. As described in further detail below, a buffer layer of the HEMT is formed to include a carbon doped aluminum gallium nitride (AlGaN:C) layer. In various examples, the AlGaN:C layer may be the uppermost layer of the buffer layer such that it is in direct contact (e.g., physical contact) with a channel layer (e.g., GaN channel layer) of the HEMT. In various examples, the AlGaN: C material layer may have a concentration of carbon of about 1×10¹⁸ cm⁻³ to about 5×10²⁰ cm⁻³, and more specifically, about 5×10¹⁸ cm⁻³ to about 1×10²⁰ cm⁻³. In various examples, the AlGaN:C layer may include equal to or less than about 10%, and more specifically, about 2% to about 10% aluminum by concentration. In various examples, the AlGaN:C layer may be about 1,000 nm to about 3,000 nm thick. In various examples, an aluminum gallium nitride (AlGaN) back-barrier layer may be formed over the AlGaN:C layer such that the AlGaN back-barrier layer is positioned between the AlGaN:C layer and the channel layer (e.g., GaN channel layer). In various examples, the AlGaN back-barrier layer may include equal to or less than about 10%, and more specifically, about 2% to about 10% aluminum by concentration. In some examples, the AlGaN back-barrier layer may include a lower concentration of aluminum than the AlGaN:C layer.

The devices and methods disclosed herein prevent or reduce the formation of pGaN stringers from occurring in HEMTs formed over miscut (or non-perpendicularly cut) semiconductor substrates (e.g., miscut silicon substrate with <111> crystallographic orientation). Specifically, pGaN stringers may be reduced or eliminated from occurring through appropriate stress and strain management during manufacturing of the HEMT. In that regard, forming the buffer layer of the HEMT may impart a compressive stress on the substrate (e.g., causing a bow in a first direction (negative Y-direction) as it is being formed). In contrast, forming the active layers (which may also be referred to as device layers) (e.g., channel layer, barrier layer, gate stack, etc.) of the HEMT impart a tensile stress on the substrate (e.g., causing a bow in a second direction (positive Y-direction) opposite the first direction) as it is being formed. Improper accounting for and/or non-balancing of these factors (e.g., stress, strain, materials and thicknesses causing stress/strain) during manufacture of a HEMT may lead to layers formed over a miscut substrate having undesirable surface roughness (e.g., stepped surface) that may cause uneven formation (e.g., inconsistent/uneven thicknesses) of subsequently formed layers thereon.

By forming a AlGaN:C layer as part of the buffer layer (e.g., in comparison to having carbon doped GaN layer as the uppermost layer of the buffer layer), the active layers formed thereover have an increased tensile strain (e.g., in comparison to the active layer formed on carbon doped GaN layer) resulting in a better coalescence of the active layers (e.g., films) as they are formed. That is, because the AlGaN:C layer causes the overlying layers to have an increased tensile strain this may effectively flatten and/or smooth the surfaces of the layers formed thereover because it counteracts the compressive strain caused by the buffer layer formed over a substrate (e.g., a miscut substrate). As a result, the surfaces of the active layers in the HEMT device have fewer deformities (e.g., steps and step edges) because of the AlGaN: C layer present in the buffer layer, which decreases the excessive accumulation of pGaN material at step edges during formation. Less accumulation of pGaN material at step edges prevents or reduces the formation of pGaN stringers during patterning of the pGaN material layer.

Disclosed herein are devices and methods that have an AlGaN:C layer as part of the buffer layer in a HEMT. Although the AlGaN:C layer adds to the compressive strain to the substrate and the buffer layer formed thereon during the manufacturing process, the active layers formed thereover may have increased tensile strain. The resulting increased tensile strain effectively flattens and/or smooths the surfaces of the layers (e.g., active layers) formed over the AlGaN:C layer. By flattening and/or smoothing the various layers of the HEMT, better coalescence of the layers is achieved as well as the prevention of pGaN stringers. There is less accumulation of the pGaN material at the step edges that may be present in the underlying material layer (e.g., barrier layer) upon which the pGaN layer is formed because the underlying material layer has fewer step edges as a result of the underlying material having a less rough or smoother top surface. This improves device performance and device yields because less accumulation of the pGaN film at the step edges results in a pGaN layer having a more even thickness, which in turn, prevents the formation of pGaN stringers during the pGaN gate etching process.

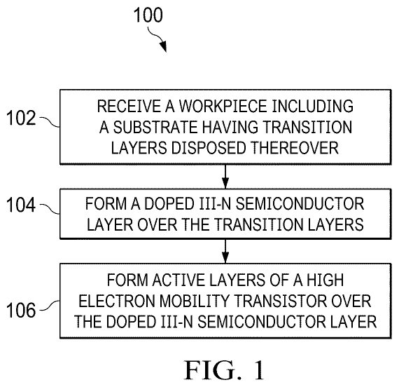

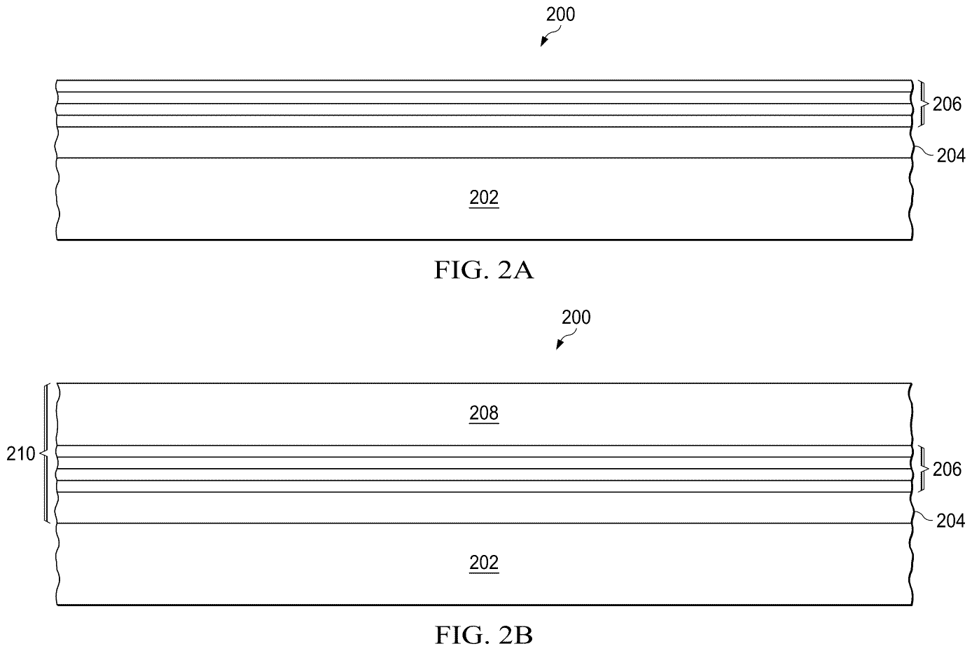

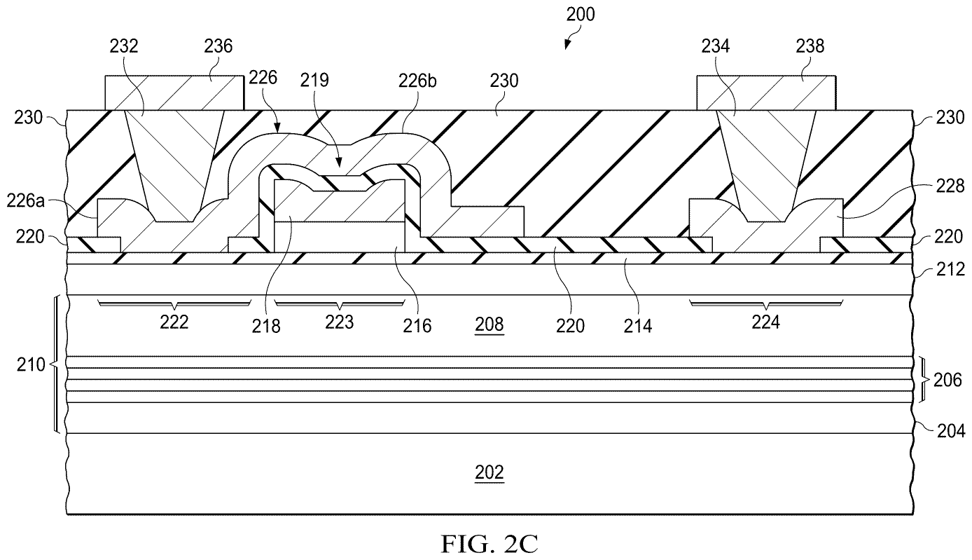

Referring now to FIG. 1, a flow diagram of a method 100 of forming a field effect transistor (FET) having an improved buffer layer is illustrated, in accordance with various examples of the present disclosure. In various examples, method 100 may be used to form a buffer layer for strain and stress managements in semiconductor devices, such as high electron mobility transistors (HEMTs). Additional processes can be provided before, during, and after method 100. As described below, method 100 is described with reference to FIGS. 2A-2C.

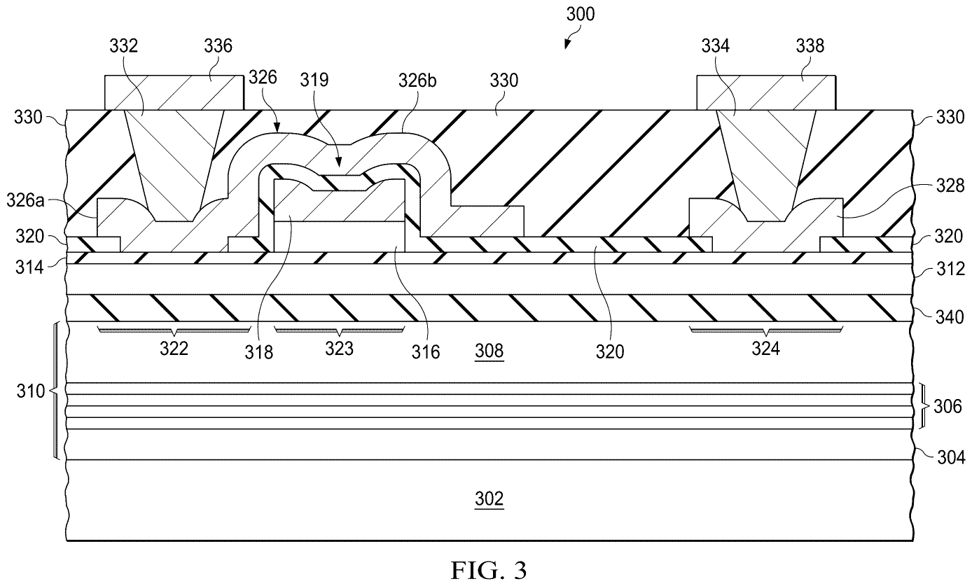

In that regard, FIGS. 2A-2C and 3 are diagrammatic cross-sectional views of a device 200 and a device 300, respectively, at various stages of fabrication (such as those associated with method 100 of FIG. 1) according to various aspects of the present disclosure. In various examples, devices 200 and 300 are or include an enhancement mode (E-mode) HEMT. Additional features can be added to device 200 and/or device 300, and some features described below can be replaced, modified, or eliminated in other examples of device 200 and/or device 300.

At step 102 of FIG. 1, a workpiece including a substrate having transition layers disposed thereover is received. As shown in FIG. 2A, device 200 includes a semiconductor substrate 202, a nucleation layer 204, and one or more transition layers 206. Nucleation layer 204 is formed over semiconductor substrate 202 and the one or more transition layers 206 are formed over nucleation layer 204. More specifically, the one or more transition layers 206 are formed over nucleation layer 204 and semiconductor substrate 202.

Semiconductor substrate 202 may be a bulk semiconductor substrate, a semiconductor-on-insulator (SOI) substrate, or any other appropriate substrate. For example, the semiconductor substrate 202 may be or include a bulk silicon wafer. In other examples, semiconductor substrate 202 may be a silicon carbide substrate or a sapphire substrate.

In some examples, semiconductor substrate 202 is cut from a silicon ingot to form a silicon substrate. In various examples, semiconductor substrate 202 may have silicon crystallographic orientation of <110>. In some examples, semiconductor substrate 202 may be a miscut wafer with a <111> crystallographic orientation (e.g., having a miscut angle of greater than about 0.2° from perpendicular as described above). In other various examples, semiconductor substrate 202 may have silicon crystallographic orientation of <110> or <100>, which may be miscut in some cases.

Nucleation layer 204 may include one or more elements that are designed to facilitate the formation of transition layers 206 over semiconductor substrate 202. In various examples, the one or more elements may include aluminum (Al), nitrogen (N₂), and/or other suitable elements. In various examples, nucleation layer 204 may include aluminum nitride (AlN).

Transition layers 206 may include any number of layers of any materials that are configured to accommodate lattice mismatch between semiconductor substrate 202 and III-N active layers formed thereover (e.g., channel layer 212 described in FIG. 2C). That is, transition layers 206 may be designed to reduce or minimize lattice defect generation and/or propagation in the channel layer (e.g., channel layer 212). For example, transition layers 206 may have a gradient concentration of one or more elements in a direction normal to the upper surface of semiconductor substrate 202. In various examples, the one or more elements my include aluminum (Al), gallium (Ga), and/or other suitable elements.

In various examples, transition layers 206 may be formed as a step structure in which each layer include different concentrations of the one or more elements of transition layers 206. For example, each of transition layers 206 may include aluminum gallium nitride (AlₓGa₍₁₋ₓ₎N) having different concentrations of aluminum and gallium. For example, nucleation layer 204 may have an aluminum concentration of 100% (e.g., AlN) and a first layer of transition layers 206 may be formed over nucleation layer 204. The first layer of transition layers may have an aluminum concentration of about 70% to about 75% and a gallium concentration of about 20% to about 25% (e.g., Al_{0.75}Ga_{0.25}N). A second layer of transition layers 206 may be formed over the first layer with the second layer having an aluminum concentration of 50% and a gallium concentration of 50% (e.g., Al_{0.5}Ga_{0.5}N). A third layer of transition layers 206 may be formed over the second layer with the third layer having an aluminum concentration of 25% and a gallium concentration of 75% (e.g., Al_{0.25}Ga_{0.75}N).

While this describes one example, transition layers 206 may include any number of layers that vary, or step, the concentration of group III elements (e.g., aluminum and gallium) from nucleation layer 204 to the channel layer (e.g., uppermost layer of transition layers 206). In some examples, each layer of transition layers 206 may have a different concentration of a first group III element (e.g., aluminum) such that the concentration of the first group III element in transition layers 206 increases in a direction towards semiconductor substrate 202. In some examples, each layer of transition layers 206 may have a different concentration of a second group III element (e.g., gallium) such that the concentration of the second group III element in transition layers 206 decreases in a direction towards semiconductor substrate 202.

In various examples, transition layers 206 may include one or more superlattice structures in which a first material layer and a second material layer are formed alternately on each other over nucleation layer 204. In various examples, each superlattice structure may include a plurality of pairs of alternating layers of the first material layer and a second material layer. In various examples, the first material layer may include aluminum nitride (AlN) and the second material layer may include aluminum gallium nitride (AlGaN). In various examples, the concentration of aluminum and gallium may be altered in each iteration of the superlattice structure. For example, the concentration of aluminum may be decreased and the concentration of gallium may be increased as the layers of the superlattice are formed over nucleation layer 204.

At step 104, a doped III-N semiconductor layer is formed over the transition layers. As shown in FIG. 2B, a doped III-N semiconductor layer 208 is formed over transition layers 206. In various examples, doped III-N semiconductor layer 208 may be or may include aluminum gallium nitride (AlGaN) and one or more dopant elements. In various examples, the one or more dopant elements may include carbon (C) or other suitable dopants. As such, in various examples, doped III-N semiconductor layer 208 is a carbon doped aluminum gallium nitride (AlGaN: C) layer. In various examples, nucleation layer 204, transition layers 206, and doped III-N semiconductor layer 208 may collectively be referred to as a III-N buffer layer 210, or buffer layer, of device 200.

Doped III-N semiconductor layer 208 is formed over transition layers 206. In various examples, doped III-N semiconductor layer 208 may be about 1,500 nm to about 3,000 nm thick, and more specifically, about 1,700 nm to about 2,500 nm thick. In various examples, doped III-N semiconductor layer 208 may have a carbon dopant concentration of about 1×10¹⁸ cm⁻³ to 5×10²⁰ cm⁻³, and more specifically, about 5×10¹⁸ cm⁻³ to 1×10²⁰ cm⁻³. In various examples, doped III-N semiconductor layer 208 may have an aluminum concentration of equal to or less than about 10%, and more specifically, about 2% to about 10%.

As described above, in various examples, doped III-N semiconductor layer 208 is a carbon doped aluminum gallium nitride (AlGaN:C) layer. The AlGaN:C layer increases compressive strain in device 200 during the manufacturing process while also allowing the active layers formed thereover to have increased tensile strain. The resulting increased tensile strain effectively flattens and/or smooths the surfaces of the layers formed over the AlGaN:C layer (e.g., by at least partially compensating the compressive strain in device 200). By flattening and/or smoothing the various layers (e.g., active layers, device layers) of the HEMT, better coalescence of the layers is achieved as well as the prevention (or reduction) of gate layer stringers (e.g., pGaN stringers) as described in more detail below.

The aluminum concentration in doped III-N semiconductor layer 208 may be attributed to build the compressive strain in device 200 without degrading the morphology (e.g., the surface of subsequent material layers) during growth. Doped III-N semiconductor layer 208 further facilitates subsequently forming active layers to establish a tensile strain. This strain and stress management results in an improved morphology and a reduction in uneven accumulation of gate layer material (e.g., pGaN) during growth thereof.

In various examples, doped III-N semiconductor layer 208 may be epitaxially grown using metal-organic chemical vapor deposition (MOCVD), molecular beam epitaxy (MBE), low pressure chemical vapor deposition (LPCVD), and/or another epitaxy process. In some examples, doped III-N semiconductor layer 208 may be in situ doped during deposition (e.g., epitaxial growth).

At step 106, active layers of a high mobility transistor are formed over the doped III-N semiconductor layer. As shown in FIG. 2C, additional layers and structures, including active layers of a high electron mobility transistor (HEMT), are formed over doped III-N semiconductor layer 208. In various examples, the additional layers and structures may include a channel layer 212, a barrier layer 214, a gate layer 216, a gate electrode 218, a passivation layer 220, a source-coupled field plate 226, a source contact 226a in a source region 222, and a drain contact 228 in a drain region 224. Furthermore, as shown in FIG. 2C, device 200 includes a dielectric layer 230, a first conductive via 232, a second conductive via 234, a first metal line 236, and a second metal line 238.

Channel layer 212 is formed over doped III-N semiconductor layer 208 and barrier layer 214 is formed over channel layer 212. Gate layer 216 is formed over barrier layer 214 and gate electrode 218 is formed over gate layer 216 to form a gate stack 219 (e.g., gate structure) over a gate region 223. Passivation layer 220 is formed over barrier layer 214, gate layer 216, and gate electrode 218. Source-coupled field plate 226 is formed over barrier layer 214 and passivation layer 220. Source-coupled field plate 226 further includes a first portion 226a (which may also be referred to as a source contact 226a) formed in source region 222 and a second portion 226b formed over gate electrode 218. Drain contact 228 is formed over barrier layer 214 and passivation layer 220 in drain region 224. Source via 232 is formed over first portion 226a of source-coupled field plate 226 and drain via 234 is formed over drain contact 228. First metal line 236 is formed over source via 232 and second metal line 238 is formed over drain via 234.

Channel layer 212 (or a first III-N semiconductor layer), in various examples, may be or may include a III-N semiconductor material. In various examples, channel layer 212 may include aluminum (Al), gallium (Ga), nitrogen (N₂), or another element as described above. In various examples, channel layer 212 includes a gallium nitride (GaN) layer and, in such examples, may be referred to as a GaN channel layer. In various examples, channel layer 212 is an undoped layer. In some examples, the material of channel layer 212 is or includes an unintentionally doped material, such as a material doped by diffusion of dopants from another layer or low levels of carbon in view of the channel layer 212 being grown using carbon based metalorganic materials. In various examples, the concentration of dopant in the unintentionally doped material may not be detectable as such is considered an undoped layer. Accordingly, in various examples, channel layer 212 may be referred to as an undoped layer or an unintentionally doped (UID) layer.

Barrier layer 214, in some examples, may be or may include an aluminum gallium nitride (AlGaN) layer and, in such examples, may be referred to as an AlGaN barrier layer (or a second III-N semiconductor layer). In some examples, channel layer 212 may be or may include indium aluminum gallium nitride (InᵢAlⱼGa₁₋ᵢ₋ⱼN) (where 0≤i≤1, 0≤j≤1, and 0≤i+j≤1), and barrier layer 214 may be or may include indium aluminum gallium nitride (InₖAlₗGa₁₋ₖ₋ₗN) (where 0≤k≤1, 0≤l≤1, and 0≤k+l≤1 ). Other materials may be implemented for channel layer 212 and/or barrier layer 214.

Channel layer 212 is configured, in conjunction with barrier layer 214, to conduct and confine charge carriers (such as electrons) within two dimensions. That is, charge carriers can be formed at an interface of such a heterojunction structure having two dissimilar semiconductor materials in contact with each other (e.g., the channel layer 212 and the barrier layer 214). In some examples, channel layer 212 and barrier layer 214 may collectively be referred to as a GaN heterojunction structure. In various examples, the charge carriers are induced at or near the surface of channel layer 212, which is in contact with barrier layer 214, at least partially due to conduction-band offset between the two semiconductor materials (e.g., GaN and AlGaN). Moreover, the charge carriers may be induced by polarization discontinuity present in the GaN heterojunction structure. Such a layer of highly mobile electrons may be referred to as a 2-dimensional electron gas (2DEG), a 2DEG layer, or charge carriers.

Gate layer 216 may then be formed over barrier layer 214. In some examples, gate layer 216 is or includes a semiconductor material to form a semiconductor material layer. Further, in some examples, gate layer 216 is doped with a dopant. In some examples, gate layer 216 is doped with a p-type dopant. Accordingly, gate layer 216 may also be referred to as a p-type III-N semiconductor material. In some examples, gate layer 216 may be or include a gallium nitride (GaN) layer, such as indium aluminum gallium nitride (InₘAlₙGa₁₋ₘ₋ₙN) (where 0≤m<1, 0≤n<1, and 0≤m+n≤1), and the dopant with which gate layer 216 is doped is a p-type dopant, which may be or include magnesium (Mg), carbon (C), zinc (Zn), the like, or a combination thereof. In examples in which gate layer 216 is gallium nitride (GaN) doped with a p-type dopant, gate layer 216 may be referred to as a p-doped GaN (pGaN) layer. Further, in examples in which gate layer 216 is gallium nitride (GaN) doped with a magnesium, gate layer 216 may be referred to as a magnesium doped gallium nitride (GaN:Mg) layer. In some examples, a concentration of the dopant in gate layer 216, which is electrically activated, is equal to or greater than 1×10¹⁷ cm⁻³. In some examples, the concentration is equal to or greater than 1×10¹⁸ cm⁻³. In some examples, the dopant in gate layer 216 may have a uniform concentration. In some examples, the dopant in gate layer 216 may have a gradient concentration. Other materials, dopants, and/or concentrations may be implemented in other examples.

As described above, by forming a doped III-N semiconductor layer 208 (e.g., a AlGaN: C layer) as part of III-N buffer layer 210, the active layers formed thereover have an increased tensile strain (e.g., in comparison to active layers formed on a buffer layer with an uppermost carbon doped GaN layer) resulting in a better coalescence of the films as they are formed. In that regard, the formation of active layers (e.g., channel layer 212 and/or barrier layer 214), in various examples, applies a tensile stress to device 200, and more specifically to semiconductor substrate 202, nucleation layer 204, transition layers 206, and doped III-N semiconductor layer 208 in addition to channel layer 212 and barrier layer 214 as they are formed. However, because device 200 includes doped III-N semiconductor layer 208 (e.g., a AlGaN:C layer) the layers formed thereover have an increased tensile strain. This increased tensile strain effectively flattens and/or smooths the surfaces of the layers formed over doped III-N semiconductor layer 208 (e.g., a AlGaN:C layer) because the increased tensile strain counteracts the compressive strain caused by the buffer layer being formed over a substrate (e.g., a miscut substrate). As a result, the surfaces of the films in the HEMT device have fewer deformities (e.g., steps and step edges) because of the doped III-N semiconductor layer 208 (e.g., a AlGaN:C layer) which decreases the excessive accumulation of gate layer material (e.g., pGaN material) at step edges during formation of gate layer 216. Less accumulation of gate layer material (e.g., pGaN material) at step edges prevents the formation of gate layer stringers (e.g., pGaN stringers) from occurring during the formation of gate layer 216.

In some examples, transition layers 206, doped III-N semiconductor layer 208, channel layer 212, barrier layer 214, and gate layer 216 may be formed by using any appropriate deposition process. In various examples, the deposition process may include an epitaxial growth process. For example, transition layers 206, doped III-N semiconductor layer 208, channel layer 212, barrier layer 214, and gate layer 216 may each be epitaxially grown using metal-organic chemical vapor deposition (MOCVD), molecular beam epitaxy (MBE), low pressure chemical vapor deposition (LPCVD), and/or another epitaxy process. In some examples, doped III-N semiconductor layer 208 may be in situ doped during deposition (e.g., epitaxial growth). In some examples, gate layer 216 may be doped in situ during deposition (e.g., epitaxial growth) or by implantation (e.g., ion implantation) subsequent to deposition.

Gate electrode 218, in various examples, may be formed using one or more deposition processes, such as sputtering, physical vapor deposition (PVD), chemical vapor deposition (CVD), or the like, or any combination thereof. In various examples, gate electrode 218 may include titanium, nickel, titanium nitride, titanium tungsten, tungsten, or a combination thereof. Other metals for gate electrode 218 are within the scope of this disclosure such that gate electrode 218 may include or be any appropriate metal and/or metal alloy.

In some examples, gate electrode 218 may form a Schottky junction with gate layer 216. As examples, when the gate layer 216 is magnesium doped gallium nitride (GaN:Mg), metal that may form a Schottky junction with gate layer 216 may be or include titanium (Ti), titanium tungsten (TiW), titanium nitride (TiN), nickel (Ni), platinum (Pt), tantalum nitride (TaN), copper (Cu), tungsten (W), or alloys thereof. In some examples, gate electrode 218 may form an ohmic junction with gate layer 216. As examples, when gate layer 216 is magnesium doped gallium nitride (GaN:Mg), metal that may form an ohmic junction with gate layer 216 may be or include gold (Au), nickel (Ni), aluminum (Al), or alloys thereof, which alloys may include titanium tungsten aluminum (TiWAl) and titanium aluminum nitride (TiAlN). In some examples, gate electrode 218 includes a first portion including a metal that forms a Schottky junction with gate layer 216 and a second portion including a metal that forms an ohmic junction with gate layer 216, such as described in U.S. patent application Ser. No. 18/361,997, filed Jul. 31, 2023, which is incorporated by reference herein in its entirety.

Passivation layer 220 (e.g., a dielectric layer) is then formed over barrier layer 214 and gate stack 219, and more specifically, over gate electrode 218. As shown, passivation layer 220 may be conformally formed over, on, and along the sidewalls and an upper surface of gate stack 219, including gate layer 216 and gate electrode 218. In some examples, passivation layer 220 may be or include silicon nitride, silicon oxide, silicon oxynitride, aluminum oxide (Al₂O₃), aluminum nitride (AlN), aluminum oxynitride (AlON), hafnium oxide (HfO₂), any other dielectric material, or a combination thereof. Passivation layer 220 may be formed by one or more low pressure chemical vapor deposition (LPCVD) processes, plasma enhanced chemical vapor deposition (PECVD) processes, high density plasma (HDP) processes, or atomic layer deposition (ALD) processes, by way of example.

Additionally, as shown, device 200 further includes source region 222 and drain region 224. A channel region extends laterally between source region 222 and drain region 224 and within channel layer 212. More specifically, the channel region underlies gate stack 219 (e.g., a gate structure). Within HEMTs, such as device 200, charge carriers (e.g., two-dimensional electron gas (2DEG)) are formed in channel layer 212, including in the channel region, source region 222, and drain region 224. For example, the charge carriers are formed at the surface of channel layer 212 that is in contact with barrier layer 214. This provides a channel for current conduction (e.g., channel layer 212) between source region 222 and drain region 224. As such, the channel region between source region 222 and drain region 224 may be referred to as a surface channel, a device channel or a transistor channel. Moreover, gate stack 219 is positioned in gate region 223 between source region 222 and drain region 224 to control the current conduction through channel layer 212.

Source-coupled field plate 226 and drain contact 228, in various examples, may be a metal or metal alloy among other conductive materials. In various examples, the metal and/or metal alloy may include aluminum (Al), cobalt (Co), silicon chromium (SiCr), and/or silicon carbide chromium (SiCCr). In various examples, the metal and/or metal alloy may include titanium nitride (TiN), tantalum nitride (TaN), titanium (Ti), aluminum (Al), copper (Cu), tungsten (W), the like, or a combination thereof. Source-coupled field plate 226 and drain contact 228 may be deposited using a physical vapor deposition (PVD) deposition method or other suitable process techniques. Source-coupled field plate 226 and/or drain contact 228 may be a single material layer or may include multiple layers of a same material composition. In various examples, the metal or metal alloy may be formed and then etched to form source-coupled field plate 226 and drain contact 228.

Source-coupled field plate 226 includes first portion 226a (which may also be referred to as source contact) and second portion 226b (e.g., etch stop, field plate). First portion 226a operates as a contact to the HEMT device and is conductively coupled to source region 222. Second portion 226b may operate as an etch stop and as a field plate for device 200. As a field plate, second portion 226b operates to reduce the maximum electric field, increase the breakdown voltage of semiconductor devices, and/or achieve a desirable electrical field profile across the channel, among other functions. As an etch stop, second portion 226b operates to cover gate stack 219 and laterally extend from the gate stack 219 to protect gate stack 219 during processing of device 200.

Dielectric layer 230 (e.g., interlayer dielectric (ILD) layer) is formed over passivation layer 220, source-coupled field plate 226, and drain contact 228. In various examples, dielectric layer 230 may be a single dielectric layer or may include multiple dielectric layers of a same dielectric material or different dielectric materials. In various examples, dielectric layer 230 may include silicon nitride, a silicon oxide-based material (such as a phosphosilicate glass (PSG) or a tetraethyl orthosilicate (TEOS) oxide), polytetrafluoroethylene, or the like.

Source via 232 and drain via 234 are formed through dielectric layer 230 and connect to first portion 226a of source-coupled field plate and drain contact 228, respectively. The metal vias may each include (i) one or more metal-barrier and/or adhesion layers (e.g., titanium nitride (TiN), tantalum nitride (TaN), the like, or a combination thereof) conformally in a respective opening through the ILD layer and (ii) a fill metal (e.g., aluminum (Al), copper (Cu), tungsten (W), the like, or a combination thereof) over and/or on the metal-barrier and/or adhesion layer(s). Also, one or more metal lines may be formed over and on (and electrically connected to) the metal vias.

First metal line 236 and second metal line 238 are formed over source via 232 and drain via 234, respectively. First metal line 236 and second metal line 238 may each include a metal and/or a metal layer including, for example, titanium nitride (TiN), tantalum nitride (TaN), aluminum (Al), copper (Cu), the like, or a combination thereof.

Although device 200 is described and shown as being an E-mode HEMT, the present disclosure is not limited to this implementation. For example, as described above, it is understood that the methods and structures disclosed herein are applicable to both E-mode HEMTs and D-mode HEMTs. That is, the improved buffer layer including the doped III-N semiconductor layer (e.g., AlGaN:C layer) as described herein can be included in any HEMT (including E-Mode and D-Mode HEMTs) independent of the presence of gate layer 216 in the gate stack.

As described above, device 200 has a doped III-N semiconductor layer 208 (e.g., AlGaN:C layer) as part of III-N buffer layer 210. This doped III-N semiconductor layer 208 (e.g., AlGaN:C layer) increases compressive strain in device 200 during the manufacturing process while also allowing the active layers (e.g., channel layer 212 and/or barrier layer 214) formed thereover to have increased tensile strain. This increased tensile strain effectively flattens and/or smooths the surfaces of the layers formed over doped III-N semiconductor layer 208 (e.g., a AlGaN:C layer) because the increased tensile strain counteracts the compressive strain caused by III-N buffer layer 210 being formed over semiconductor substrate 202 (e.g., miscut substrate).

By flattening and/or smoothing the various layers of the HEMT, better coalescence of the layers is achieved as well as the prevention of stringers associated with gate layer 216 (e.g., pGaN stringers) formation. There is less accumulation of the material (e.g., pGaN material) used to form gate layer 216 at the step edges that may be present in the underlying material layer (e.g., barrier layer 214) upon which gate layer 216 (e.g., pGaN layer) is formed. This is because the underlying material layer (e.g., barrier layer 214) has fewer step edges as a result of the underlying material having a less rough, or smoother, top surface as a result of using doped III-N semiconductor layer 208 (e.g., AlGaN:C layer) as part of III-N buffer layer 210.

The incorporation of a doped III-N semiconductor layer 208 (e.g., AlGaN:C layer) as part of III-N buffer layer 210 in device 200 improves device performance and device yields. Specifically, because III-N buffer layer 210 includes doped III-N semiconductor layer 208 (e.g., AlGaN:C layer), there is less accumulation of the material (e.g., pGaN material) used to form gate layer 216 at the step edges in the underlying material layer (e.g., barrier layer 214) which results in gate layer 216 (e.g., pGaN layer) having a more constant thickness. A more constant thickness (e.g., even/consistent/uniform thickness) for gate layer 216 prevents the formation of gate layer stringers (e.g., pGaN stringers) from occurring. This is because etching a gate layer 216 having a more constant thickness allows for a more even etch process which avoids unintended portions of the gate layer remaining unetched outside gate region 223. As a result, the formation of gate layer stringers (e.g., pGaN stringers) is prevented (or reduced) in device 200.

Referring now to FIG. 3, a diagrammatic cross-sectional view of a device 300 is shown at various stages of fabrication (such as those associated with method 100 of FIG. 1), according to various aspects of the present disclosure. In various examples, device 300 is or includes an enhancement mode (E-mode) HEMT. Additional features can be added to device 300, and some features described below can be replaced, modified, or eliminated in other examples of device 300.

As shown in FIG. 3, device 300 is includes similar layers to device 200 described above in FIGS. 2A-2C. For example, device 300 similarly includes a semiconductor substrate 302, a nucleation layer 304, a transition layers 306, a doped III-N semiconductor layer 308, a buffer layer 310, a channel layer 312, a barrier layer 314, a gate layer 316, a gate electrode 318, a gate stack 319, a passivation layer 320, a source region 322, a gate region 323, a drain region 324, a source-coupled field plate 326 including a source contact 326a and a second portion 326b, a drain contact 328, a dielectric layer 330, a source via 332, a drain via 334, a first metal line 336, and a second metal line 338. For simplicity and clarity, the description of these similar features is not repeated here.

Unlike device 200, device 300 further includes a III-N back-barrier layer 340, or back-barrier layer, formed over doped III-N semiconductor layer 308 prior to the formation of channel layer 312. That is, back-barrier layer 340 is positioned between doped III-N semiconductor layer 308 and channel layer 312. In various examples, III-N back-barrier layer 340 may be considered part of buffer layer 310 or may be considered as a separate layer from buffer layer 310.

III-N back-barrier layer 340, in various examples, may include a III-N semiconductor material. In various examples, III-N back-barrier layer 340 may have a thickness of about 25 nm to about 200 nm, and more specifically, about 50 nm to about 150 nm. In various examples, III-N back-barrier layer 340 may be or may include aluminum gallium nitride (AlGaN). In various examples, III-N back-barrier layer 340 may have an aluminum concentration of equal to or less than about 10%, and more specifically, about 2% to about 10%. In some examples, III-N back-barrier layer 340 has the same aluminum concentration as doped III-N semiconductor layer 308. In other examples, III-N back-barrier layer 340 has a different aluminum concentration than doped III-N semiconductor layer 308. That is, in some examples, III-N back-barrier layer 340 has a greater or lesser aluminum concentration than doped III-N semiconductor layer 308.

Additionally, in some examples, III-N back-barrier layer 340 may be doped. For example, III-N back-barrier layer 340 may be extrinsically doped with carbon or other similar dopants. As such, in some examples, III-N back-barrier layer 340 may be considered a doped III-N semiconductor layer (e.g., a carbon doped aluminum gallium nitride layer). In various examples, III-N back-barrier layer 340 and doped III-N semiconductor layer 308 may be doped with the same dopant (e.g., carbon). In some examples, III-N back-barrier layer 340 may have the same dopant (e.g., carbon) concentration as doped III-N semiconductor layer 308. In other examples, III-N back-barrier layer 340 may have a different dopant (e.g., carbon) concentration than doped III-N semiconductor layer 308. That is, in some examples, III-N back-barrier layer 340 has a greater or lesser dopant (e.g., carbon) concentration than doped III-N semiconductor layer 308.

In other examples, III-N back-barrier layer 340 may be an undoped material layer. That is, III-N back-barrier layer 340 may not be intentionally doped but may be unintentionally doped because of doped III-N semiconductor layer 308. However, the amount of dopant in III-N back-barrier layer 340 may be undetectable such that III-N back-barrier layer 340 may be considered either undoped or unintentionally doped. In some examples, III-N back-barrier layer 340 includes low levels of carbon in view of the III-N back-barrier layer 340 being grown using carbon based metalorganic materials. In some examples, the dopant (e.g., carbon) from doped III-N semiconductor layer 308 may inadvertently diffuse into III-N back-barrier layer 340 at a level that is undetectable such that III-N back-barrier layer 340, in this example, may be considered either undoped or unintentionally doped.

As described above, disclosed herein are devices and methods for managing the strain and stress of the various material layers that are formed in order to increase the yield of high electron mobility transistor (HEMT) devices formed over miscut substrates (or wafers). As described above, the buffer layer of the HEMT device that may interface with the active layers (e.g., the channel layer) of the HEMT device, is formed to include a doped III-N semiconductor layer (e.g., carbon doped aluminum gallium nitride (AlGaN:C)). This doped III-N semiconductor layer (e.g., AlGaN:C layer) increases compressive strain in the HEMT during the manufacturing process while also allowing active layers (e.g., channel layer and/or barrier layer) formed thereover to have increased tensile strain. This increased tensile strain effectively flattens and/or smooths the surfaces of the layers formed over doped III-N semiconductor layer (e.g., a AlGaN:C layer) because the increased tensile strain counteracts the compressive strain caused by buffer layer being formed over a miscut substrate.

By flattening and/or smoothing the various layers of the HEMT, better coalescence of the layers is achieved as well as the prevention of stringers associated with the formation of the gate layer of the HEMT. There is less accumulation of the material (e.g., pGaN material) used to form the gate layer at the step edges that may be present in the underlying material layer (e.g., barrier layer) upon which the gate layer (e.g., pGaN layer) is formed thereon. This is because the underlying material layer (e.g., barrier layer) has fewer step edges as a result of the underlying material having a less rough or smoother top surface by using a doped III-N semiconductor layer (e.g., AlGaN:C layer) as part of the buffer layer.

The incorporation of a doped III-N semiconductor layer (e.g., AlGaN:C layer) as part of a buffer layer in a HEMT improves device performance and device yields. Specifically, because the buffer layer includes a doped III-N semiconductor layer (e.g., AlGaN:C layer), there is less accumulation of the material (e.g., pGaN material) used to form gate layer at the step edges in the underlying material layer (e.g., barrier layer) results in the gate layer (e.g., pGaN layer) having a more constant thickness. A more constant thickness (e.g., even/consistent thickness) for the gate layer prevents the formation of gate layer stringers (e.g., pGaN stringers) from occurring. This is because etching a gate layer having a more constant thickness allows for a more even etch process which avoids unintended portions of the gate layer remaining unetched. As a result, the formation of gate layer stringers (e.g., pGaN stringers) is prevented in the HEMT device.

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A device, comprising:
a III-N buffer layer disposed over a substrate, the III-N buffer layer including a carbon doped aluminum gallium nitride layer;
a first III-N material layer disposed over and interfacing with the carbon doped aluminum gallium nitride layer;
a second III-N material layer disposed over the first III-N material layer, the first and second III-N material layers forming a heterojunction structure, wherein the first III-N material layer includes a channel proximate to an interface between the first and second III-N material layers; and
a gate structure disposed over the second III-N material layer.

2. The device of claim 1, wherein the carbon doped aluminum gallium nitride layer has a concentration of aluminum of equal to or less than about 10%.

3. The device of claim 1, wherein the carbon doped aluminum gallium nitride layer has a carbon concentration of about 1×10¹⁸ cm⁻³ to about 5×10²⁰ cm⁻³.

4. The device of claim 1, wherein the substrate is a silicon substrate including a surface having a <111> crystallographic orientation, and
wherein the III-N buffer layer is disposed over the surface of the silicon substrate.

5. The device of claim 1, wherein the III-N buffer layer further includes a plurality of third III-N material layers,
wherein each layer of the plurality of third III-N material layers has a different concentration of a group III element such that the concentration of the group III element in the plurality of third III-N material layers increases in a direction towards the substrate, and
wherein the carbon doped aluminum gallium nitride layer is disposed over the plurality of third III-N material layers.

6. The device of claim 1, wherein the III-N buffer layer further includes a plurality of alternating layers of a third III-N material layer and a fourth III-N material layer, the third III-N material layer and the fourth III-N material layer having different material compositions, and
wherein the carbon doped aluminum gallium nitride layer is disposed over the plurality of alternating layers of the third III-N material layer and the fourth III-N material layer.

7. The device of claim 1, wherein the second III-N material layer includes an aluminum gallium nitride (AlGaN) material, and
wherein the gate structure includes a p-type doped gallium nitride (GaN) layer and a metal layer disposed over the p-type doped GaN layer.

8. A device, comprising:
a III-N buffer layer disposed over a substrate, the III-N buffer layer including a carbon doped aluminum gallium nitride layer;
a III-N back-barrier layer disposed over the III-N buffer layer;
a first III-N material layer disposed over the III-N back-barrier layer;
a second III-N material layer disposed over the first III-N material layer, the first and second III-N material layers forming a heterojunction structure, wherein the first III-N material layer includes a channel proximate an interface between the first and second III-N material layers; and
a gate structure disposed over the second III-N material layer.

9. The device of claim 8, wherein the III-N back-barrier layer includes aluminum gallium nitride (AlGaN).

10. The device of claim 9, wherein the III-N back-barrier layer has a lower concentration of aluminum than the carbon doped aluminum gallium nitride layer.

11. The device of claim 8, wherein the III-N back-barrier layer interfaces with the carbon doped aluminum gallium nitride layer of the III-N buffer layer.

12. The device of claim 11, wherein the III-N back-barrier layer further interfaces with the first III-N material layer.

13. The device of claim 8, wherein the carbon doped aluminum gallium nitride layer has a carbon concentration of equal to or less than about 10%.

14. The device of claim 8, wherein the substrate is a silicon substrate including a surface having a <111> crystallographic orientation, and
wherein the III-N buffer layer is disposed over the surface of the silicon substrate.

15. The device of claim 8, wherein the first III-N material layer includes gallium nitride (GaN),
wherein the second III-N material layer includes aluminum gallium nitride (AlGaN), and
wherein the gate structure includes a p-type doped gallium nitride (GaN) layer and a metal layer disposed over the p-type doped GaN layer.

16. A method comprising:
forming a carbon doped aluminum gallium nitride layer over a substrate;
forming a first III-N material layer over the carbon doped aluminum gallium nitride layer;
forming a second III-N material layer on the first III-N material layer, the first and second III-N material layers forming a heterojunction structure, wherein the first III-N material layer includes a channel proximate to an interface between the first and second III-N material layers; and
forming a gate structure over the second III-N material layer.

17. The method of claim 16, wherein forming the first III-N material layer over the carbon doped aluminum gallium nitride layer includes forming the first III-N material layer directly on the carbon doped aluminum gallium nitride layer such that the first III-N material layer interfaces with the carbon doped aluminum gallium nitride layer.

18. The method of claim 16, further comprising:
forming a III-N back-barrier layer over the carbon doped aluminum gallium nitride layer prior to forming the first III-N material layer over the carbon doped aluminum gallium nitride layer.

19. The method of claim 18, wherein forming the III-N back-barrier layer over the carbon doped aluminum gallium nitride layer includes forming the III-N back-barrier layer directly on the carbon doped aluminum gallium nitride layer such that the III-N back-barrier layer interfaces with the carbon doped aluminum gallium nitride layer.

20. The method of claim 19, wherein the III-N back-barrier layer includes aluminum gallium nitride.

21. The method of claim 16, wherein forming the carbon doped aluminum gallium nitride layer includes forming the carbon doped aluminum gallium nitride layer to have a carbon concentration of about 1×10¹⁸ cm⁻³ to about 5×10²⁰ cm⁻³ and a concentration of aluminum of equal to or less than about 10%.

22. The method of claim 16, further comprising:
forming a plurality of third III-N material layers over the substrate, wherein each layer of the plurality of third III-N material layers has a different concentration of a group III element such that the concentration of the group III element in the plurality of third III-N material layers increases in a direction towards the substrate, and
wherein forming the carbon doped aluminum gallium nitride layer over the substrate includes forming the carbon doped aluminum gallium nitride layer over the plurality of third III-N material layers.

23. The method of claim 16, further comprising:
forming a plurality of alternating layers of a third III-N material layer and a fourth III-N material layer over the substrate, the third III-N material layer and the fourth III-N material layer having different material compositions, and
wherein forming the carbon doped aluminum gallium nitride layer over the substrate includes forming the carbon doped aluminum gallium nitride layer over the plurality of alternating layers.
